(19) United States
(12) Patent Application Publication
(10) Pub. No.: US 2026/0088773 A1
(43) Pub. Date: Mar. 26, 2026

(54) POWER AMPLIFIER EFFICIENCY AND LINEARITY IN A WIRELESS TRANSMISSION CIRCUIT

(71) Applicant: Qorvo US, Inc., Greensboro, NC (US)

(72) Inventors: Nadim Khlat, Ceret (FR); George Maxim, Saratoga, CA (US); Baker Scott, San Jose, CA (US); Ming Ji, Melrose, MA (US); Woo Yong Lee, Chapel Hill, NC (US)

(21) Appl. No.: 19/329,653

(22) Filed: Sep. 16, 2025

Related U.S. Application Data
(60) Provisional application No. 63/697,643, filed on Sep. 23, 2024.

(51) Int. Cl. H03F 1/02; H03F 1/32; H03F 3/24; H04B 1/04

(52) U.S. Cl. CPC H03F 1/0288; H03F 1/32; H03F 3/245; H04B 1/0475; H03F 2200/451

(57) ABSTRACT

Improving power amplifier efficiency and linearity in a wireless transmission circuit is disclosed. Like conventional Doherty power amplifiers, a power amplifier circuit disclosed herein amplifies a signal using a carrier path and a peaking path. Contrary to activating the peaking path based on a conventional feedback-based activation scheme, the power amplifier circuit is configured to activate the peaking path based on a feedforward activation scheme. Specifically, the power amplifier circuit is configured to receive an envelope signal that is time-aligned with a time-variant power envelope of the signal to be amplified therein. Herein, the power amplifier circuit is configured to process the envelope signal to ensure that activation of the peaking path tracks compression of the carrier path under various local environmental conditions. As a result, it is possible to improve efficiency and linearity of the power amplifier circuit across a wide modulation bandwidth and under various local environmental conditions.

### RELATED APPLICATIONS

This application claims the benefit of U.S. provisional patent application Ser. No. 63/697,643, filed on Sep. 23, 2024, the disclosure of which is hereby incorporated herein by reference in its entirety.

### FIELD OF THE DISCLOSURE

The technology of the disclosure relates generally to improving efficiency and linearity of a Doherty power amplifier in a wireless transmission circuit.

### BACKGROUND

Fifth generation (5G) has been widely regarded as the next generation of wireless communication technology. As such, a wireless communication device capable of supporting 5G wireless communication technology is expected to achieve higher data rates, improved coverage range, enhanced signaling efficiency, and reduced latency. The continuous drive towards higher efficiencies, particularly when processing a radio frequency (RF) signal with a large peak-to-average ratio (PAR) and wide modulation bandwidth, creates both opportunities and challenges for utilizing Doherty power amplifiers in wireless communications.

A typical Doherty power amplifier includes a carrier amplifier and a peaking amplifier. The carrier amplifier is always active to amplify an RF signal, whereas the peaking amplifier is only activated when the carrier amplifier runs into compression to further amplify the RF signal to a higher power level. As a result, the Doherty power amplifier can achieve a desirable level of efficiency in the face of a large PAR of the RF signal.

Conventionally, the peaking amplifier can be activated based on a feedback-based activation scheme, wherein a feedback activation loop is used to detect a compression point at which the carrier amplifier starts compressing and activate the peaking amplifier accordingly. Such feedback-based peaking amplifier activation may work well when the RF signal is modulated with a lower to moderate modulation bandwidth (e.g., up to 30-40 MHz). However, a group delay in the feedback activation loop can occur when the RF signal is modulated with a much higher modulation bandwidth (e.g., >100 MHz), as often seen in mid-high band (MHB) and ultra-high band (UHB) in 5G communication systems. As such, it is desirable to optimize the conventional feedback-based activation scheme to help improve efficiency and linearity of the Doherty power amplifier across a wide modulation bandwidth of the RF signal.

### SUMMARY

Embodiments of the disclosure relate to improving power amplifier efficiency and linearity in a wireless transmission circuit. Like a conventional Doherty power amplifier, a power amplifier circuit disclosed herein amplifies a signal using a carrier path and a peaking path. Contrary to activating the peaking path based on a conventional feedback-based activation scheme, the power amplifier circuit is configured to activate the peaking path based on a feedforward activation scheme. Specifically, the power amplifier circuit is configured to receive an envelope signal (e.g., from a transceiver circuit) that is time-aligned with a time-variant power envelope of the signal to be amplified therein. Herein, the power amplifier circuit is configured to process the envelope signal (e.g., by analog and/or digital means) to ensure that activation of the peaking path tracks compression of the carrier path under various local environmental conditions. By activating the peaking path based on the feedforward activation scheme, it is possible to improve efficiency and linearity of the power amplifier circuit across a wide modulation bandwidth and under various local environmental conditions.

In one aspect, a power amplifier circuit is provided. The power amplifier circuit includes a carrier path. The carrier path is configured to amplify a signal up to a compression power threshold based on a supply voltage. The power amplifier circuit also includes a peaking path. The peaking path is activated above the compression power threshold to further amplify the signal based on the supply voltage. The power amplifier circuit also includes a power amplifier control circuit. The power amplifier control circuit is configured to receive an envelope signal that is time-aligned with a time-variant power envelope of the signal at the power amplifier circuit. The power amplifier control circuit is also configured to generate one or more peaking path control signals each corresponding to a respective power threshold and having a respective slope based on the envelope signal to thereby activate the peaking path above the compression power threshold. The power amplifier control circuit is also configured to generate one or more carrier path control signals based on the envelope signal to thereby boost an amplitude gain response of the carrier path prior to activation of the peaking path and thereby reduce a gain response jump of the peaking path during the activation of the peaking path.

In another aspect, a method for improving power amplifier efficiency and linearity in a power amplifier circuit is provided. The method includes amplifying a signal up to a compression power threshold in a carrier path based on a supply voltage. The method also includes activating a peaking path above the compression power threshold to further amplify the signal based on the supply voltage. The method also includes receiving an envelope signal that is time-aligned with a time-variant power envelope of the signal at the power amplifier circuit. The method also includes generating one or more peaking path control signals each corresponding to a respective power threshold and having a respective slope based on the envelope signal to thereby activate the peaking path above the compression power threshold. The method also includes generating one or more carrier path control signals based on the envelope signal to boost an amplitude gain response of the carrier path prior to activation of the peaking path and thereby reduce a gain response jump of the peaking path during the activation of the peaking path.

In another aspect, a wireless transmission circuit is provided. The wireless transmission circuit includes a transceiver circuit. The transceiver circuit includes a baseband circuit. The baseband circuit is configured to generate a digital signal. The transceiver circuit also includes a signal processing circuit.

The signal processing circuit is configured to convert the digital signal into a signal having a time-variant power envelope. The wireless transmission circuit also includes a power management integrated circuit (PMIC). The PMIC is configured to generate a supply voltage based on a configuration signal received from the transceiver circuit. The wireless transmission circuit also includes a power amplifier circuit. The power amplifier circuit includes a carrier path. The carrier path is configured to amplify the signal up to a compression power threshold based on the supply voltage. The power amplifier circuit also includes a peaking path. The peaking path is activated above the compression power threshold to further amplify the signal based on the supply voltage. The power amplifier circuit also includes a power amplifier control circuit. The power amplifier control circuit is configured to receive an envelope signal that is time-aligned with a time-variant power envelope of the signal at the power amplifier circuit. The power amplifier control circuit is also configured to generate one or more peaking path control signals each corresponding to a respective power threshold and having a respective slope based on the envelope signal to thereby activate the peaking path above the compression power threshold. The power amplifier control circuit is also configured to generate one or more carrier path control signals based on the envelope signal to boost an amplitude gain response of the carrier path prior to activation of the peaking path and thereby reduce a gain response.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a schematic diagram of an exemplary power amplifier circuit configured according to an embodiment of the present disclosure to activate a peaking path based on a peaking path control signal generated from an envelope signal;

FIG. 2A is a graphic diagram providing an exemplary illustration of an overall gain response of the power amplifier circuit of FIG. 1;

FIG. 2B is a graphic diagram providing an exemplary illustration as to how local environmental conditions in the power amplifier circuit of FIG. 1 can impact a timing for activating the peaking path;

FIG. 3 is a graphic diagram providing exemplary illustrations as to how the power amplifier circuit of FIG. 1 can activate the peaking path based on the peaking path control signal;

FIG. 4 is a schematic diagram of an exemplary power amplifier circuit configured according to another embodiment of the present disclosure to activate the peaking path based on different peaking path control signals generated from the envelope signal;

FIG. 5 is a graphic diagram providing exemplary illustrations as to how the power amplifier circuit of FIG. 4 can activate the peaking path based on different peaking path control signals;

FIG. 6 is a schematic diagram of an exemplary power amplifier circuit configured according to an embodiment to improve amplitude-amplitude (AM-AM) and amplitude-phase (AM-PM) linearities in both peaking and carrier paths;

FIG. 7 is a schematic diagram of an exemplary peaking path control circuit configured according to another embodiment to improve AM-AM and AM-PM linearities in the peaking path;

FIG. 8 is a schematic diagram of a wireless transmission circuit configured to incorporate the power amplifier circuits of FIGS. 1, 4, and 6 according to an embodiment of the present disclosure;

FIGS. 9A and 9B are schematic diagrams providing exemplary illustrations as to how the power amplifier circuits in FIG. 8 can receive and process the envelope signal from a transceiver circuit;

FIG. 10 is a schematic diagram of a wireless transmission circuit configured according to another embodiment of the present disclosure;

FIG. 11 is a schematic diagram of a wireless transmission circuit configured according to another embodiment of the present disclosure;

FIG. 12 is a schematic diagram of an exemplary communication device wherein the wireless transmission circuits of FIGS. 8, 10, and 11 can be provided; and

FIG. 13 is a flowchart of an exemplary process for improving efficiency and linearity in the power amplifier circuit of FIGS. 1, 4, and 6.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to power amplifier efficiency and linearity in a wireless transmission circuit. Like a conventional Doherty power amplifier, a power amplifier circuit disclosed herein amplifies a signal using a carrier path and a peaking path. Contrary to activating the peaking path based on a conventional feedback-based activation scheme, the power amplifier circuit is configured to activate the peaking path based on a feedforward activation scheme. Specifically, the power amplifier circuit is configured to receive an envelope signal (e.g., from a transceiver circuit) that is time-aligned with a time-variant power envelope of the signal to be amplified therein. Herein, the power amplifier circuit is configured to process the envelope signal (e.g., by analog and/or digital means) to ensure that activation of the peaking path tracks compression of the carrier path under various local environmental conditions. By activating the peaking path based on the feedforward activation scheme, it is possible to improve efficiency and linearity of the power amplifier circuit across a wide modulation bandwidth and under various local environmental conditions.

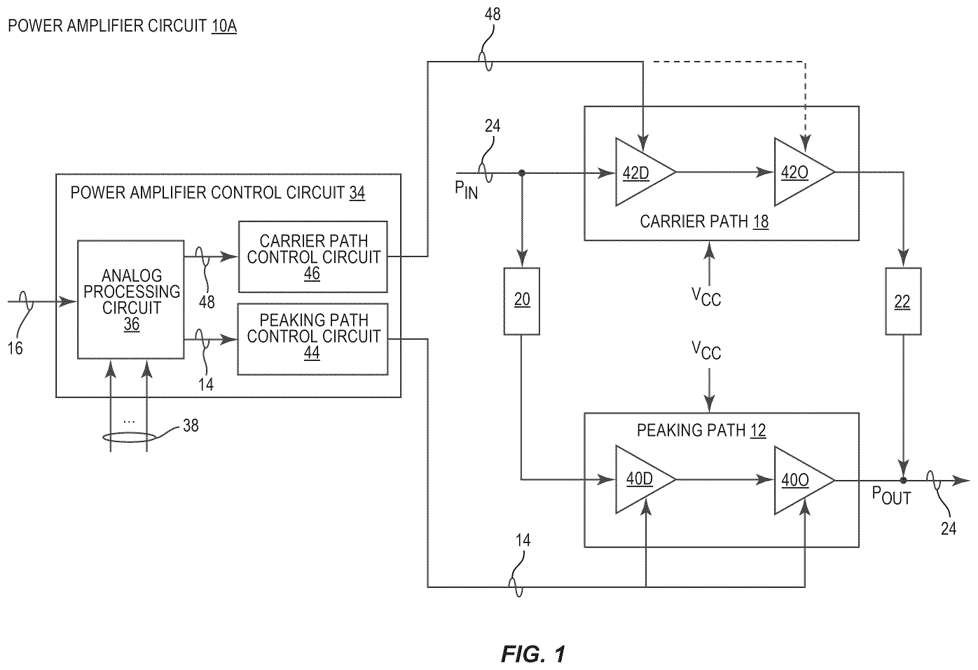

FIG. 1 is a schematic diagram of an exemplary power amplifier circuit 10A configured according to an embodiment of the present disclosure to activate a peaking path 12 based on a peaking path control signal 14 generated from an envelope signal 16. In an embodiment, the power amplifier circuit 10A is a Doherty power amplifier that further includes a carrier path 18, an input splitter 20, and an output combiner 22. The carrier path 18 is always active to amplify a signal 24 from a time-variant input power P_{IN} up to a compression power threshold (a.k.a. compression point) based on a supply voltage V_{CC}. As a gain response of the carrier path 18 starts declining above the compression point, the peaking path 12 is activated to further amplify the signal 24 based on the supply voltage V_{CC}. In this regard, the power amplifier circuit 10A will operate with only the carrier path 18 when the time-variant input power P_{IN} or an expected output power P_{OUT} of the signal 24 is below the compression power threshold. When the time-variant input power P_{IN} or the expected output power P_{OUT} of the signal 24 is above the compression power threshold, the power amplifier circuit 10A will then operate with both the carrier path 18 and the peaking path 12. As such, the power amplifier circuit 10A can be well suited to amplify the signal 24, particularly when the signal 24 is associated with a large peak-to-average ratio (PAR).

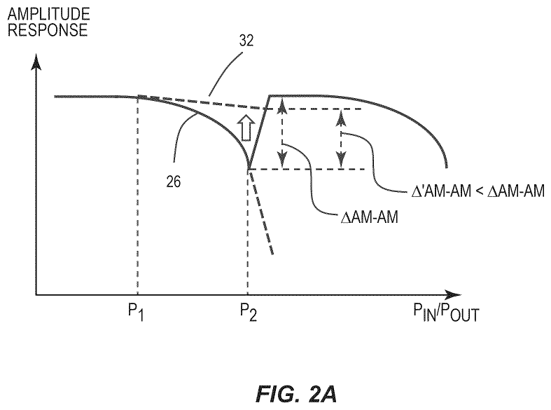

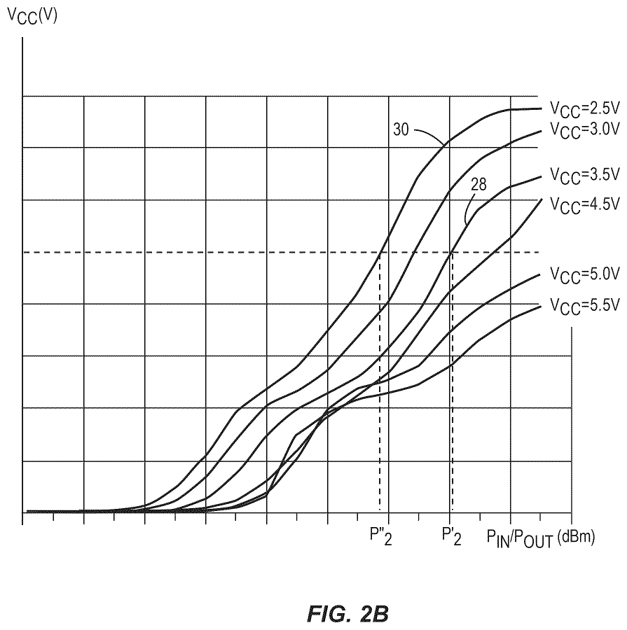

FIG. 2A is a graphic diagram providing an exemplary illustration of an overall amplitude gain response 26 of the power amplifier circuit 10A of FIG. 1. Herein, the overall amplitude gain response 26 is influenced by a compression power threshold P₁ and a peaking activation threshold P₂ (P₂≥P₁). When the time-variant input power P_{IN} is below the compression power threshold P₁, only the carrier path 18 is active to amplify the signal 24. Above the compression power threshold P₁, the carrier path 18 starts compressing and, as a result, the overall amplitude gain response 26 of the power amplifier circuit 10A starts to decline. As such, the peaking path 12 will be activated at the peaking activation threshold P₂ to thereby boost the overall amplitude gain response 26 of the power amplifier circuit 10A.

From a perspective of the power amplifier circuit 10A, activating the peaking path 12 right at the compression power threshold P₁ will result in a lower overall efficiency. In this regard, it may be best to delay activation of the peaking path 12 to the peaking activation threshold P₂ (P₂>P₁). However, since the carrier path 18 will have already started compressing at the compression power threshold P₁, the power amplifier circuit 10A will inevitably suffer some level of compression between the compression power threshold P₁ and the peaking activation threshold P₂. Moreover, the longer the delay in activating the peaking path 12, the sharper a gain response jump ΔAM-AM will be experienced by the power amplifier circuit 10A when the peaking path 12 is activated, which can lead to unacceptable distortions.

Furthermore, the timing for activating the peaking path 12 can be influenced by a variety of local environmental conditions, which may include variations of the supply voltage V_{CC}, temperature variations, load voltage standing wave ratio (VSWR) variations, semiconductor process variations, and/or part-to-part variations.

FIG. 2B is a graphic diagram providing an exemplary illustration as to how local environmental conditions, such as variations of the supply voltage V_{CC}, in the power amplifier circuit 10A of FIG. 1 can impact the timing for activating the peaking path 12. As shown herein, when the supply voltage V_{CC} is higher (e.g., at 3.5 V as indicated by a first V_{CC} control curve 28), the power amplifier circuit 10A will have more headroom and, as a result, the carrier path 18 will start compressing later. As such, the peaking path 12 needs to be activated later at a peaking activation threshold P′₂ to help boost efficiency of the power amplifier circuit 10A. In contrast, when the supply voltage V_{CC} is lower (e.g., at 2.5 V as indicated by a second V_{CC} control curve 30), the power amplifier circuit 10A will have less headroom to work with and, as a result, the carrier path 18 will start compressing sooner. As such, the peaking path 12 needs to be activated earlier at a peaking activation threshold P″₂ (P″₂<P′₂) to help maintain efficiency of the power amplifier circuit 10A.

In an embodiment, a family of possible V_{CC} control curves (including the first V_{CC} control curve 28 and the second V_{CC} control curve 30) can be pre-stored in a lookup table (LUT) in a local memory (not shown) or dynamically generated with an analog means from the envelope signal 16. Accordingly, a supply voltage detector (not shown) may be provided in the power amplifier circuit 10A to dynamically detect a level of the supply voltage V_{CC} and then determine the peaking activation threshold (e.g., P′₂ or P″₂) in accordance with the detected level of the supply voltage V_{CC}.

Needless to say, the other local environmental conditions (e.g., temperature, load VSWR, semiconductor processes, and/or part-to-part variations) may also have a respective impact on when to activate the peaking path 12. As such, it is necessary to further take into consideration these local environmental conditions when determining when and how the peaking path 12 should be activated.

Notably, some of the variations (e.g., temperature and VSWR variations) may be dynamic, whereas some other variations (e.g., semiconductor processes and part-to-part variations) may be static. Like the supply voltage V_{CC}, it is possible to pre-store a family of dynamic local environmental dependencies (e.g., temperature and load VSWR) in a respective LUT. Accordingly, various detectors (e.g., temperature and load VSWR detectors) may be provided in the power amplifier circuit 10A to dynamically detect such local environmental variations. As for the static local environmental variations (e.g., semiconductor processes and part-to-part variations), it may be possible to employ a calibration circuit (not shown) in the power amplifier circuit 10A to help compensate for the impact of such static local environmental variations.

With reference back to FIG. 2A, as mentioned earlier, for the sake of efficiency improvement, it may be better to delay the peaking activation threshold P₂ above the compression power threshold P₁. In this regard, it is necessary to boost linearity of the carrier path 18 between the compression power threshold P₁ and the peaking activation threshold P₂ to thereby maintain overall linearity of the power amplifier circuit 10A. As an example, it is necessary to boost the amplitude gain response 26 of the carrier path 18 to a higher amplitude gain response 32 prior to activation of the peaking path 12 at the peaking activation threshold P₂. Understandably, by boosting the amplitude gain response 26 to the higher amplitude gain response 32, the power amplifier circuit 10A will instead experience a smaller (a.k.a. reduced) gain response jump Δ′AM-AM (Δ′AM-AM<ΔAM-AM) when the peaking path 12 is activated. As a result, it is possible to reduce the unacceptable distortions associated with the activation of the peaking path 12 in the power amplifier circuit 10A.

With reference back to FIG. 1, in an embodiment, the power amplifier circuit 10A is configured to include a power amplifier control circuit 34. The power amplifier control circuit 34 receives the envelope signal 16. As further discussed below, the envelope signal 16 may be generated outside the power amplifier circuit 10A (e.g., in a transceiver circuit) or locally inside the power amplifier circuit 10A. Regardless of where the envelope signal 16 is generated, the envelope signal 16 has been pre-processed by digital and/or analog means to be time-aligned with the time-variant power envelope of the signal 24 at the power amplifier circuit 10. In other words, the envelope signal 16 and the signal 24 will arrive at the power amplifier circuit 10A simultaneously.

The power amplifier control circuit 34 includes an analog processing circuit 36. In an embodiment, the analog processing circuit 36 is configured to process the envelope signal 16 to generate the peaking path control signal 14. In a non-limiting example, the analog processing circuit 36 can perform analog pre-distortion (APD) on the envelope signal 16 based on one or more local environmental variations 38, such as variations of the supply voltage V_{CC}, temperature, and/or load VSWR to thereby correct the compression characteristics of the carrier path 18. More specifically, the envelope signal 16 is pre-distorted not only to ensure proper alignment between the compression power threshold P₁ and the peaking activation threshold P₂, but also to introduce one or more threshold points in the peaking path control signal 14 to each correspond to a respective slew rate (a.k.a. slope) that can help improve overall linearity of the power amplifier circuit 10A.

In an embodiment, the peaking path 12 includes a peaking driver amplifier 40D and a peaking output amplifier 40O that are coupled in series. Similarly, the carrier path 18 includes a carrier driver amplifier 42D and a carrier output amplifier 420 that are coupled in series. Accordingly, the power amplifier control circuit 34 may include a peaking path control circuit 44 and a carrier path control circuit 46 that are configured to control the peaking path 12 and the carrier path 18, respectively.

In an embodiment, the peaking path control circuit 44 is configured to activate both the peaking driver amplifier 40D and the peaking output amplifier 400 concurrently using the peaking path control signal 14. The analog processing circuit 36 is further configured to generate a carrier path control signal 48 from the envelope signal 16. As an example, the analog processing circuit 36 can generate the carrier path control signal 48 by performing APD on the envelope signal 16. The carrier path control circuit 46, in turn, controls the carrier driver amplifier 42D with the carrier path control signal 48 to help improve overall linearity of the power amplifier circuit 10A before and after the peaking path 12 is activated. In an embodiment, the carrier path control signal 48 may also be used to control the carrier output amplifier 420 to further improve overall linearity.

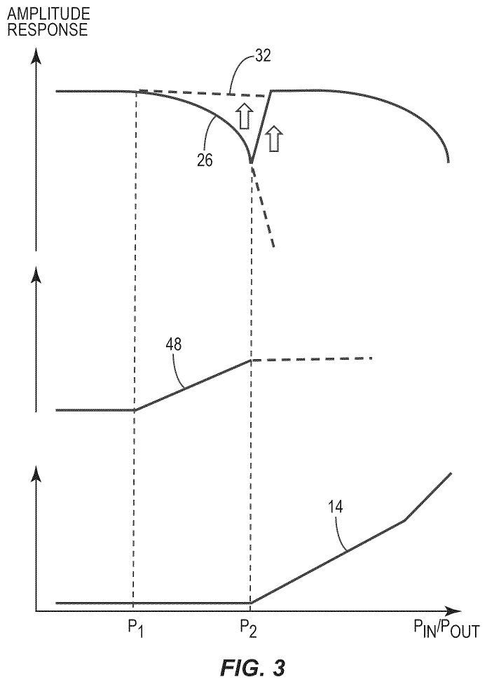

FIG. 3 is a graphic diagram providing an exemplary illustration as to how the peaking path control signal 14 and the carrier path control signal 48 can collectively improve efficiency and linearity of the power amplifier circuit 10A of FIG. 1 before and after activation of the peaking path 12. Common elements between FIGS. 2A and 3 are shown therein with common element numbers and will not be re-described herein.

Herein, the carrier path control signal 48 is generated to boost the amplitude gain response 26 to the higher amplitude gain response 32 between the compression power threshold P₁ and the peaking activation threshold P₂. As previously discussed in FIG. 2A, the carrier path control signal 48 can help prevent the power amplifier circuit 10A from showing significant gain compression before the peaking path 12 is activated at the peaking activation threshold P₂.

The peaking path control signal 14, on the other hand, will activate the peaking driver amplifier 40D and the peaking output amplifier 40O concurrently at the peaking activation threshold P₂. In an embodiment, both the peaking path control signal 14 and the carrier path control signal 48 are automatic gain control (AGC) signals derived from the envelope signal 16. Nevertheless, the peaking path control signal 14 and the carrier path control signal 48 can be associated with different threshold points. Specifically, the carrier path control signal 48 is associated with the compression power threshold P₁, whereas the peaking path control signal 14 is associated with the peaking activation threshold P₂. In addition, the carrier path control signal 48 will require a smaller gain change or dynamic range (e.g., 2-3 dB) to enable AGC on the carrier driver amplifier 42D. In contrast, the peaking path control signal 14 requires a larger gain change or dynamic range (e.g., ≥20 dB) to enable AGC on the peaking driver amplifier 40D and the peaking output amplifier 40O. In this regard, activating the peaking driver amplifier 40D and the peaking output amplifier 40O concurrently may lead to a fast ramp up of the output power P_{OUT} at the expense of an increased current consumption and a slightly reduced efficiency.

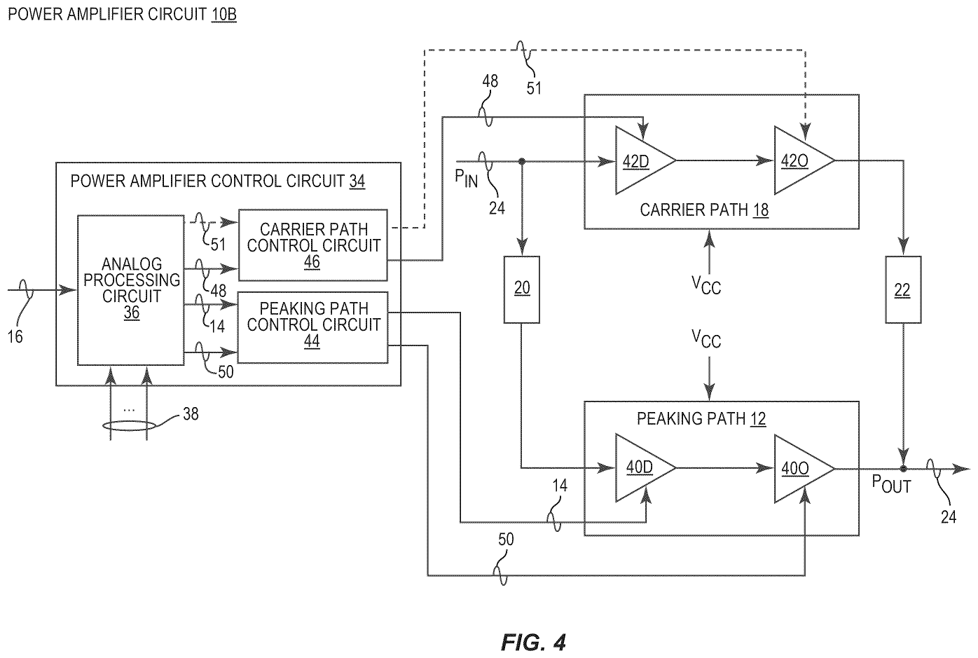

To help reduce the current consumption when activating the peaking path 12, FIG. 4 is a schematic diagram of an exemplary power amplifier circuit 10B configured according to another embodiment of the present disclosure to activate the peaking path 12 sequentially. Common elements between FIGS. 1 and 4 are shown therein with common element numbers and will not be re-described herein.

Herein, the analog processing circuit 36 is configured to further generate a second peaking path control signal 50 from the envelope signal 16. Accordingly, the peaking path control circuit 44 can first activate the peaking driver amplifier 40D with the peaking path control signal 14 and then activate the peaking output amplifier 40O with the second peaking path control signal 50. In an embodiment, the peaking path control circuit 44 may activate the peaking output amplifier 40O via either bias-kicking or AGC. In an embodiment, the analog processing circuit 36 may also be configured to further generate a second carrier path control signal 51 from the envelope signal 16. Accordingly, the carrier path control circuit 46 can first control the carrier driver amplifier 42D with the carrier path control signal 48 and then control the carrier output amplifier 420 with the second carrier path control signal 51, or vice versa. As an example, the carrier path control circuit 46 can control the carrier output amplifier 420 via bias-kicking.

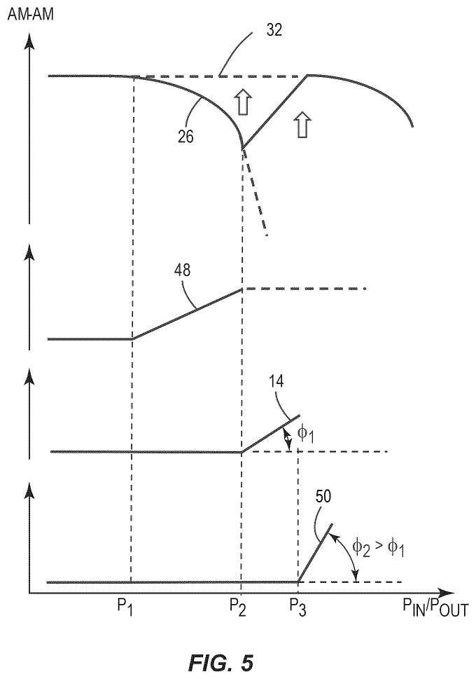

FIG. 5 is a graphic diagram providing an exemplary illustration as to how the peaking path control circuit 44 in FIG. 4 can utilize the peaking path control signal 14 and the second peaking path control signal 50 to sequentially activate the peaking driver amplifier 40D and the peaking output amplifier 40O.

Common elements between FIGS. 3 and 5 are shown therein with common element numbers and will not be re-described herein.

Herein, the peaking path control signal 14 is provided to the peaking driver amplifier 40D at the peaking activation threshold P₂ to thereby bring up the peaking driver amplifier 40D from deep class-C to help boost back-off efficiency and maintain battery linearity. Subsequently, at a second peaking activation threshold P₃ (P₃>P₂), the second peaking path control signal 50 is provided to the peaking output amplifier 40O only to ramp up the last 1 to 1.5 dB of the output power P_{OUT}.

In this regard, the analog processing circuit 36 will associate the peaking path control signal 14 with the peaking activation threshold P₂ and a respective slope φ₁ (a.k.a. slew rate). The analog processing circuit 36 will also associate the second peaking path control signal 50 with the second peaking activation threshold P₃ and a respective slope φ₂ (a.k.a. slew rate). In a non-limiting example, the slope φ₂ can be greater than the slope φ₁ to ramp up the peaking output amplifier 40O quickly. The peaking activation threshold P₂ and the second peaking activation threshold P₃ may be determined based on a most common PAR of the signal 24. In a non-limiting example, for a 6 dB Doherty power amplifier, the second peaking activation threshold P₃ may be approximately 4 dB higher than the peaking activation threshold P₂.

With reference back to FIG. 4, the high efficiency of the power amplifier circuit 10B depends on sharp activation of the peaking path 12, which is ensured by controlling the gain of the peaking driver amplifier 40D and/or the peaking output amplifier 40O. However, the overall linearity of the power amplifier circuit 10B depends on amplitude-amplitude (AM-AM) and amplitude-phase (AM-PM) linearities of the carrier path 18 before activation of the peaking path 12, as well as AM-AM and AM-PM linearities of the peaking path 12 during and after activation of the peaking path 12. As such, the analog processing circuit 36 may be configured to perform analog pre-distortion (APD) on the envelope signal 16 to help achieve desired AM-AM and AM-PM linearities before, during, and after activation of the peaking path 12.

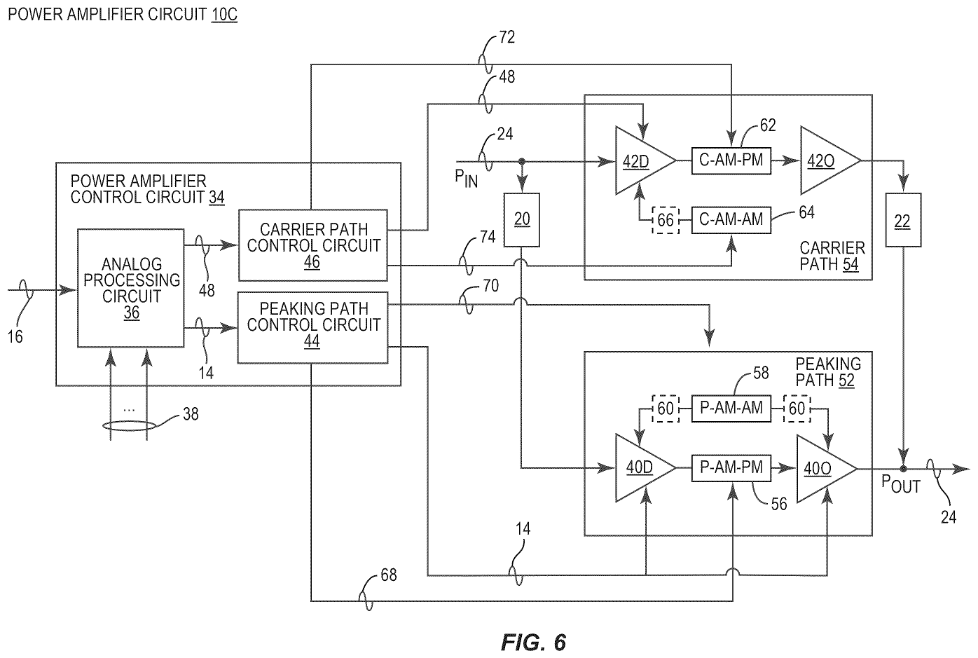

In this regard, FIG. 6 is a schematic diagram of an exemplary power amplifier circuit 10C configured according to an embodiment of the present disclosure to improve AM-AM and AM-PM linearities in a peaking path 52 and a carrier path 54 before, during, and after activation of the peaking path 52. Common elements between FIGS. 1 and 6 are shown therein with common element numbers and will not be re-described herein.

Herein, the peaking path 52 includes a peaking AM-PM linearization circuit 56 and a peaking AM-AM linearization circuit 58. The peaking AM-PM linearization circuit 56 is coupled in between the peaking driver amplifier 40D and the peaking output amplifier 40O. The peaking AM-AM linearization circuit 58 is coupled to, for example, respective collector nodes (not shown), of the peaking driver amplifier 40D and the peaking output amplifier 40O via a pair of peaking bias circuits 60.

Similarly, the carrier path 54 includes a carrier AM-PM linearization circuit 62 and a carrier AM-AM linearization circuit 64. The carrier AM-PM linearization circuit 62 is coupled in between the carrier driver amplifier 42D and the carrier output amplifier 420. The carrier AM-AM linearization circuit 64 is coupled to, for example, a respective collector node (not shown), of the carrier driver amplifier 42D via a carrier bias circuit 66.

Specifically, the carrier AM-PM linearization circuit 62 is configured to correct AM-PM phase distortion in the carrier path 54 before activation of the peaking path 52, whereas the peaking AM-PM linearization circuit 56 is configured to correct AM-PM phase distortion in the peaking path 52 during and after activation of the peaking path 52.

The carrier AM-AM linearization circuit 64 is configured to act on the gain of the carrier driver amplifier 42D to thereby ensure gain linearity of the carrier path 54 before activation of the peaking path 52. The peaking AM-AM linearization circuit 58, on the other hand, is configured to act on both the peaking driver amplifier 40D and the peaking output amplifier 40O via, for example, AGC or bias-kicking, to thereby ensure fast activation and high linearity during and after activation of the peaking path 52.

In an embodiment, the peaking path control circuit 44 may be configured to generate a peaking AM-PM linearization control signal 68 and a peaking AM-AM linearization control signal 70 for controlling the peaking AM-PM linearization circuit 56 and the peaking AM-AM linearization circuit 58, respectively. Likewise, the carrier path control circuit 46 may be configured to generate a carrier AM-PM linearization control signal 72 and a carrier AM-AM linearization control signal 74 for controlling the carrier AM-PM linearization circuit 62 and the carrier AM-AM linearization circuit 64, respectively.

In an embodiment, the peaking AM-PM linearization control signal 68 and the peaking AM-AM linearization control signal 70 may be combined with the peaking path control signal 14. In another embodiment, the peaking AM-PM linearization control signal 68 and the peaking AM-AM linearization control signal 70 may be separate signals from the peaking path control signal 14. In this regard, the peaking path control circuit 44 may generate the peaking AM-PM linearization control signal 68 and the peaking AM-AM linearization control signal 70 based on the local environmental variations 38, as used by the analog processing circuit 36 for processing the envelope signal 16.

Similarly, the carrier AM-PM linearization control signal 72 and the carrier AM-AM linearization control signal 74 may be combined with the carrier path control signal 48. In another embodiment, the carrier AM-PM linearization control signal 72 and the carrier AM-AM linearization control signal 74 may be separate signals from the carrier path control signal 48. In this regard, the carrier path control circuit 46 may generate the carrier AM-PM linearization control signal 72 and the carrier AM-AM linearization control signal 74 based on the local environmental variations 38, as used by the analog processing circuit 36 for processing the envelope signal 16.

While the envelope signal 16 is used for linearizing both the peaking path 52 and the carrier path 54, different envelope processing blocks may be used to produce distinct activation points and slopes for the AM-AM and AM-PM linearization. For example, the AM-AM linearization may have a stronger temperature dependence, while the AM-PM linearization may have a stronger load dependence, which may lead to different threshold points and/or slopes. As such, it may be desirable to perform AM-AM and AM-PM linearization based on different sets of local environmental variations.

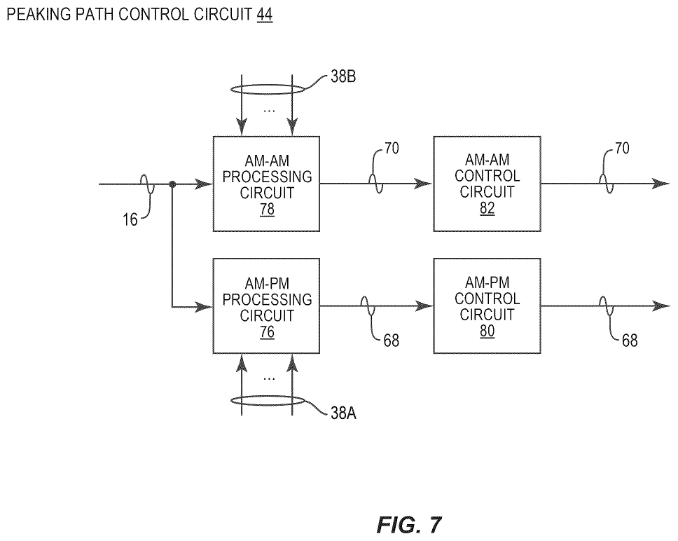

In this regard, FIG. 7 is a schematic diagram providing an exemplary illustration of the peaking path control circuit 44 in FIG. 6 configured to improve AM-PM and AM-AM linearities in the peaking path 12 based on different sets of local environmental variations 38A, 38B. Common elements between FIGS. 6 and 7 are shown therein with common element numbers and will not be re-described herein.

In an embodiment, the peaking path control circuit 44 can include an AM-PM processing circuit 76, an AM-AM processing circuit 78, an AM-PM control circuit 80, and an AM-AM control circuit 82. The AM-PM processing circuit 76 is configured to pre-distort the envelope signal 16 based on a respective set of local environmental variations 38A to thereby generate the peaking AM-PM linearization control signal 68. The AM-PM control circuit 80 is configured to control the peaking AM-PM linearization circuit 56 based on the peaking AM-PM linearization control signal 68. The AM-AM processing circuit 78 is configured to pre-distort the envelope signal 16 based on a respective set of local environmental variations 38B to thereby generate the peaking AM-AM linearization control signal 70. The AM-AM control circuit 82 is configured to control the peaking AM-AM linearization circuit 58 based on the peaking AM-AM linearization control signal 70.

Notably, the peaking path control circuit 44 is discussed herein merely as an example. It should be appreciated that the carrier path control circuit 46 may be configured to operate in a similar fashion.

The power amplifier circuit 10A of FIG. 1, the power amplifier circuit 10B of FIG. 4, and the power amplifier circuit 10C of FIG. 6 may be provided in a wireless communication circuit in a wireless device in accordance with multiple embodiments.

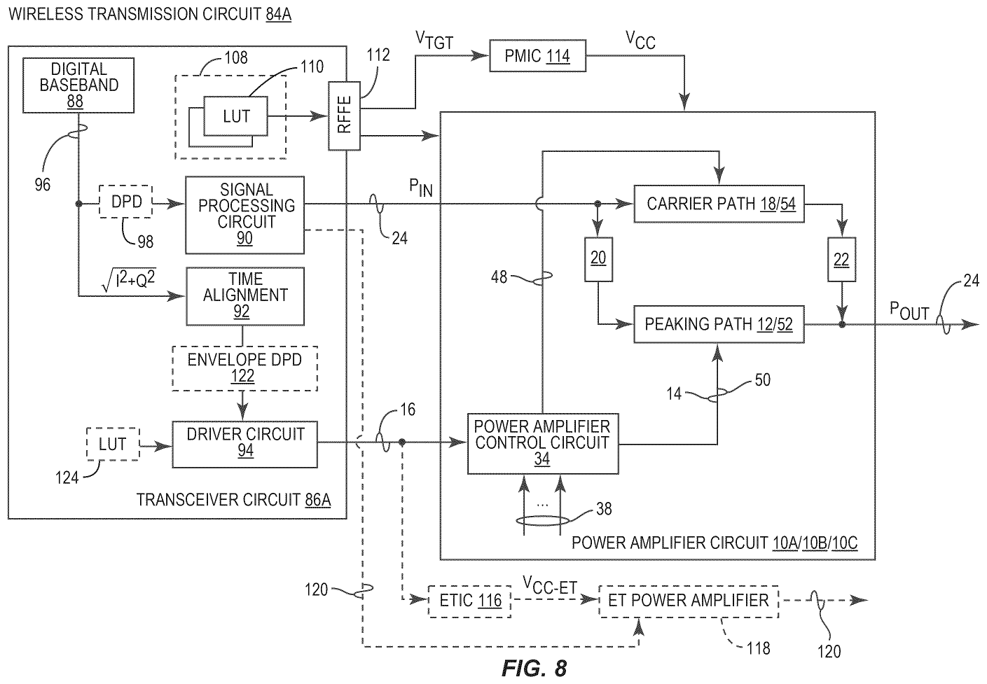

FIG. 8 is a schematic diagram of a wireless transmission circuit 84A configured to incorporate the power amplifier circuits of FIGS. 1, 4, and 6 according to an embodiment of the present disclosure. Common elements between FIGS. 1, 4, 6, and 8 are shown therein with common element numbers and will not be re-described herein.

Herein, the wireless transmission circuit 84A includes a transceiver circuit 86A, which includes a digital baseband circuit 88, a signal processing circuit 90, a time alignment circuit 92, and a driver circuit 94. The digital baseband circuit 88 is configured to generate a digital signal 96 having an in-phase (I) component and a quadrature (Q) component. Accordingly, the digital signal 96 is associated with a time-variant amplitude \sqrt{I²+Q²}. The signal processing circuit 90 is configured to process the digital signal 96 to thereby generate the signal 24. Since the signal 24 is generated from the digital signal 96, the time-variant power envelope of the signal 24 will therefore track the time-variant amplitude \sqrt{I²+Q²} of the digital signal 96. The transceiver circuit 86A may include a digital pre-distortion (DPD) circuit 98 that can digitally pre-distort the digital signal 96 to help improve linearization, before converting the digital signal 96 into the signal 24.

The time alignment circuit 92 is configured to digitally advance or delay the digital signal 96 to thereby ensure that the time-variant amplitude \sqrt{I²+Q²} of the digital signal 96 is substantially time-aligned with the time-variant power envelope of the signal 24. The driver circuit 94 is configured to generate the envelope signal 16 from the time-aligned digital signal 96 and provide the envelope signal 16 to the power amplifier control circuit 34.

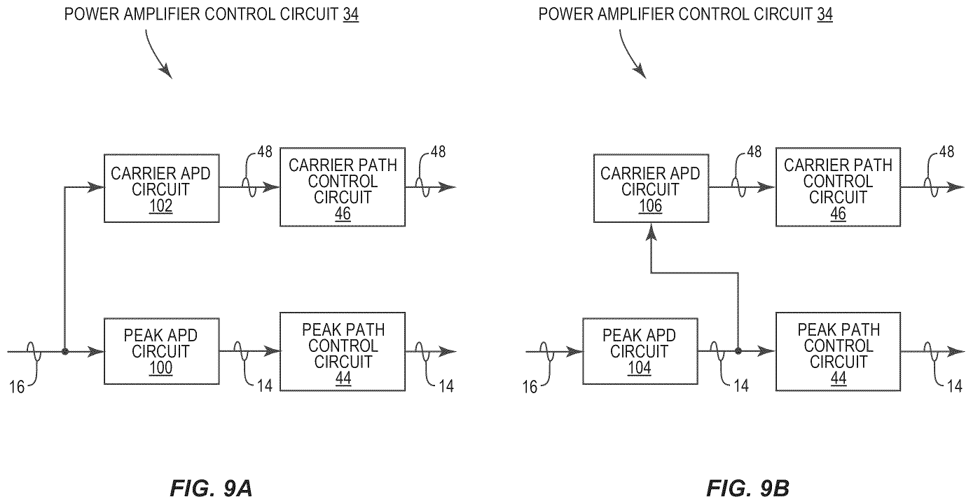

Generally speaking, it is desirable to employ as few signal lines as possible between the transceiver circuit 86A and any of the power amplifier circuits 10A, 10B, and 10C, particularly those signal lines for communicating signals with significant bandwidth as these analog signal lines can consume a considerable amount of current and require sufficient shielding to prevent parasitic coupling from a noisy environment. In this regard, FIGS. 9A and 9B are schematic diagrams providing exemplary illustrations as to how any of the power amplifier circuits 10A, 10B, and 10C in FIG. 8 can receive the envelope signal 16 from the transceiver circuit 86A. Common elements between FIGS. 8, 9A, and 9B are shown therein with common element numbers and will not be re-described herein.

With reference to FIG. 9A, a peak APD circuit 100 is configured to generate the peaking path control signal 14 from the envelope signal 16 and a carrier APD circuit 102 is configured to generate the carrier path control signal 48 from the envelope signal 16.

With reference to FIG. 9B, a peak APD circuit 104 is configured to first generate the peaking path control signal 14 from the envelope signal 16. A carrier APD circuit 106 is then configured to generate the carrier path control signal 48 from the peaking path control signal 14. Such a configuration is easy to implement if a simple relation (e.g., a fixed offset between their respective threshold points or a fixed relation between their respective slopes) exists between the peaking path control signal 14 and the carrier path control signal 48.

With reference back to FIG. 8, the transceiver circuit 86A can further include a storage device 108 (e.g., register bank or flash memory) that is configured to store one or more lookup tables (LUTs) 110. The LUTs 110 may be configured to store configuration parameters to provide the configuration parameters to any of the power amplifier circuits 10A, 10B, and 10C via, for example, a radio frequency frontend (RFFE) interface 112.

The wireless transmission circuit 84A can include a power management integrated circuit (PMIC) 114. The PMIC 114 is configured to generate the supply voltage V_{CC} in accordance with a voltage target V_{TGT} received from the transceiver circuit 86A.

In an embodiment, the wireless transmission circuit 84A may further include an envelope tracking integrated circuit (ETIC) 116. The ETIC 116 is configured to generate an envelope tracking (ET) voltage V_{CC-ET} based on the envelope signal 16 and provide the ET voltage V_{CC-ET} to an ET power amplifier circuit 118 for amplifying an ET signal 120. In a non-limiting example, the signal processing circuit 90 can be configured to generate and provide the ET signal 120 to the ET power amplifier circuit 118.

In one embodiment, the transceiver circuit 86A is configured to only generate the envelope signal 16. In this regard, the power amplifier control circuit 34 needs to pre-distort the envelope signal 16 to thereby generate the peaking path control signal 14, the carrier path control signal 48, and the second peaking path control signal 50.

In another embodiment, the transceiver circuit 86A may include an envelope DPD circuit 122. The envelope DPD circuit 122 may be configured to perform some level of DPD on the time-aligned digital signal 96 based on parameters pre-stored in an envelope LUT 124. In this regard, the power amplifier control circuit 34 only needs to perform analog pre-distortion on the envelope signal 16 based on the local environmental variations 38 to thereby generate the peaking path control signal 14, the carrier path control signal 48, and the second peaking path control signal 50.

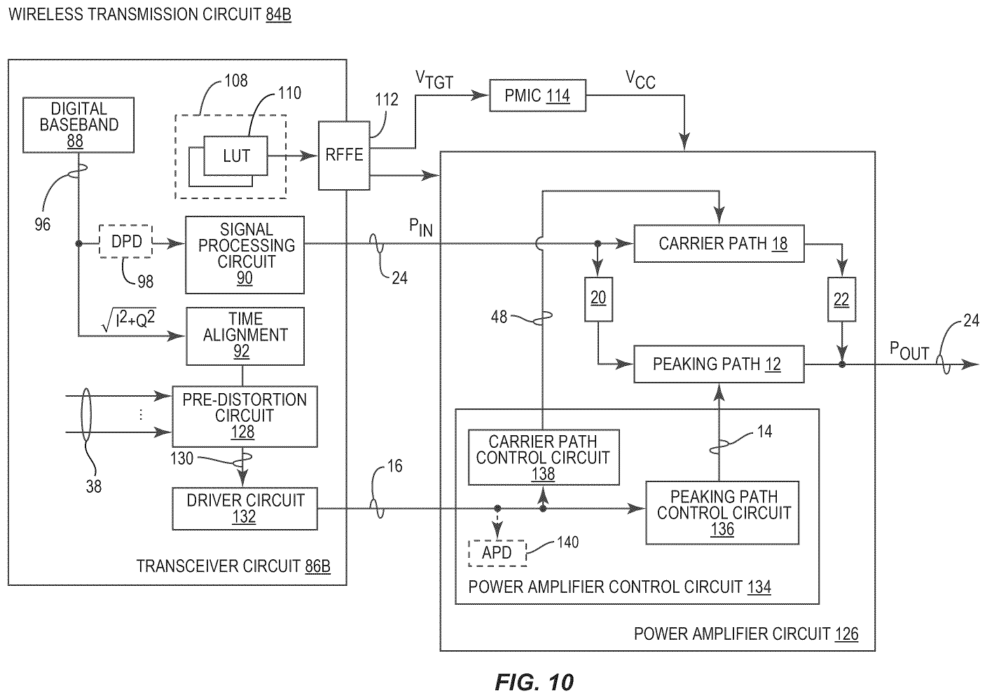

Notably, since the transceiver circuit 86A can be made with a finer complementary metal-oxide semiconductor (CMOS) process to provide much larger storage and processing (digital and analog) capabilities, it may be desirable to pre-distort the envelope signal 16 inside the transceiver circuit 86A. In this regard, FIG. 10 is a schematic diagram of a wireless transmission circuit 84B configured according to another embodiment of the present disclosure to pre-distort the envelope signal 16 inside the transceiver circuit 86B. Common elements between FIGS. 8 and 10 are shown therein with common element numbers and will not be re-described herein.

Herein, the wireless transmission circuit 84B includes a transceiver circuit 86B and a power amplifier circuit 126. Like the transceiver circuit 86A in FIG. 8, the transceiver circuit 86B is also configured to digitally process the digital signal 96 to thereby time-align the time-variant amplitude \sqrt{I²+Q²} of the digital signal 96 with the time-variant power envelope of the signal 24. In addition, the transceiver circuit 86B includes a pre-distortion circuit 128 that is configured to pre-distort the time-aligned digital signal 96 based on the local environmental variations 38 to thereby generate a pre-distorted digital envelope signal 130. The transceiver circuit 86B also includes a driver circuit 132, which is configured to generate the envelope signal 16 from the pre-distorted digital envelope signal 130.

The power amplifier circuit 126 includes a power amplifier control circuit 134, which can include a peaking path control circuit 136 and a carrier path control circuit 138. The peaking path control circuit 136 is configured to generate the peaking path control signal 14 from the envelope signal 16 for activating the peaking path 12. The carrier path control circuit 138 is configured to generate the carrier path control signal 48 for improving linearity of the carrier path 18. In an embodiment, the power amplifier control circuit 134 may further include an APD circuit 140 to perform analog pre-distortion on the envelope signal 16 to help further improve linearity of the power amplifier circuit 126.

As previously discussed, the local environmental variations 38 can include variations in the supply voltage V_{CC}, variations in the power amplifier temperature, and variations in the load VSWR. Herein, the transceiver circuit 86B knows exactly how the supply voltage V_{CC} should be changed (e.g., timing and value) to amplify the signal 24 to a desired output power level. The transceiver circuit 86B may not have knowledge with respect to the power amplifier temperature and load VSWR but can nevertheless obtain such information from the power amplifier circuit 126.

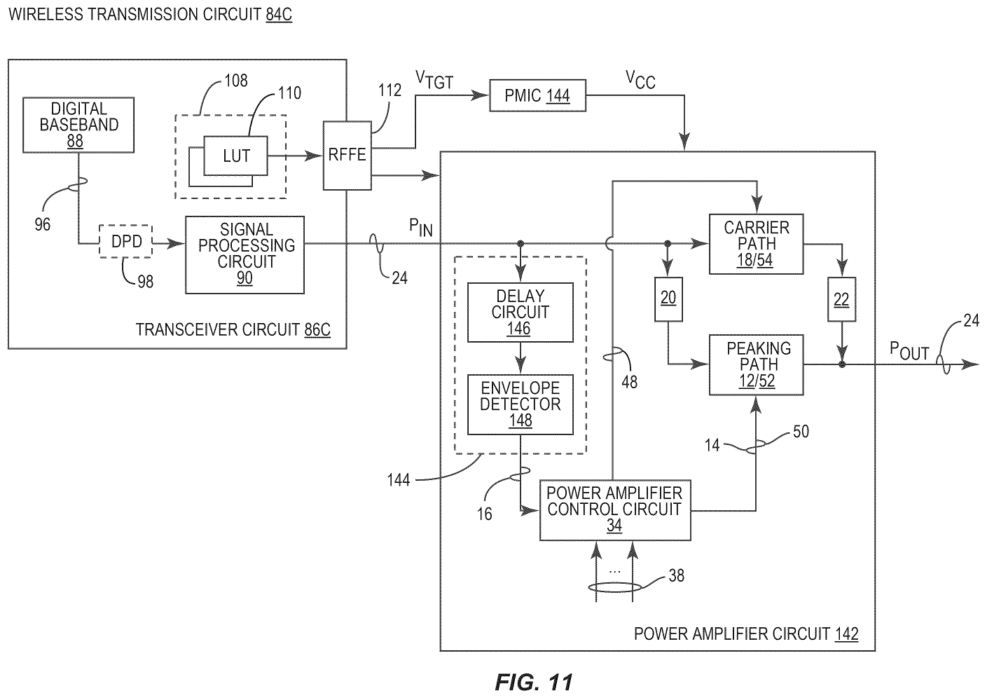

To reduce dependencies on the transceiver circuit 86B, the power amplifier circuit 126 may be adapted to generate the envelope signal 16 locally based on the time-variant power envelope of the signal 24. In this regard, FIG. 11 is a schematic diagram of a wireless transmission circuit 84C wherein a power amplifier circuit 142 is configured according to another embodiment of the present disclosure to generate the envelope signal 16 based on the time-variant power envelope of the signal 24. Common elements between FIGS. 8 and 11 are shown therein with common element numbers and will not be re-described herein.

Herein, the power amplifier circuit 142 includes an envelope processing circuit 144 configured to generate the envelope signal 16 based on the time-variant power envelope of the signal 24 and time-align the envelope signal 16 with the time-variant power envelope of the signal 24. Specifically, the envelope processing circuit 144 includes a delay circuit 146 and an envelope detector 148. The delay circuit 146 is configured to delay the signal 24 to ensure time alignment between the envelope signal 16 and the time-variant power envelope of the signal 24. The envelope detector 148 is configured to generate the envelope signal 16 from the time-variant power envelope of the signal 24.

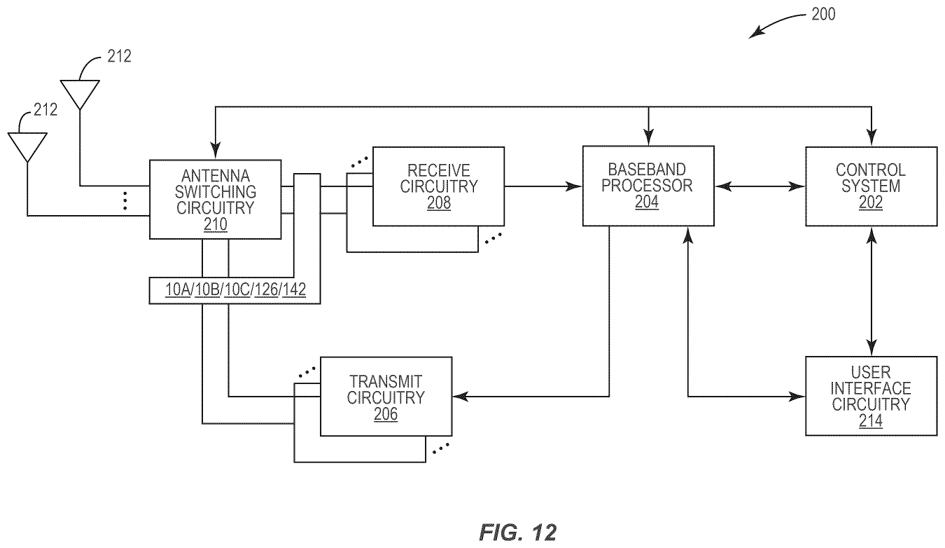

The power amplifier circuit 10A of FIG. 1, the power amplifier circuit 10B of FIG. 4, the power amplifier circuit 10C of FIG. 6, the power amplifier circuit 126 in FIG. 10, and the power amplifier circuit 142 in FIG. 11 can be provided in a communication device (e.g., a wireless device) to support the embodiments described above. In this regard, FIG. 12 is a schematic diagram of an exemplary communication device 200 wherein the power amplifier circuit 10A of FIG. 1, the power amplifier circuit 10B of FIG. 4, the power amplifier circuit 10C of FIG. 6, the power amplifier circuit 126 in FIG. 10, and the power amplifier circuit 142 in FIG. 11 can be provided.

Herein, the communication device 200 can be any type of communication devices, such as mobile terminals, smart watches, tablets, computers, navigation devices, access points, base stations (e.g., eNB, gNB, etc.), and any other type of wireless communication devices that support wireless communications, such as cellular, wireless local area network (WLAN), Bluetooth, Ultra-wideband (UWB), and near field communications. The communication device 200 will generally include a control system 202, a baseband processor 204, transmit circuitry 206, receive circuitry 208, antenna switching circuitry 210, multiple antennas 212, and user interface circuitry 214. In a non-limiting example, the control system 202 can be a field-programmable gate array (FPGA), as an example. In this regard, the control system 202 can include at least a microprocessor(s), an embedded memory circuit(s), and a communication bus interface(s). The receive circuitry 208 receives radio frequency signals via the antennas 212 and through the antenna switching circuitry 210 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 204 processes the digitized received signal to extract the information or data bits conveyed in the received signal. This processing typically comprises demodulation, decoding, and error correction operations, as will be discussed in greater detail below. The baseband processor 204 is generally implemented in one or more digital signal processors (DSPs) and application specific integrated circuits (ASICs).

For transmission, the baseband processor 204 receives digitized data, which may represent voice, data, or control information, from the control system 202, which it encodes for transmission. The encoded data is output to the transmit circuitry 206, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 212 through the antenna switching circuitry 210. The multiple antennas 212 and the replicated transmit and receive circuitries 206, 208 may provide spatial diversity. Modulation and processing details will be understood by those skilled in the art.

In an exemplary embodiment, the transmit circuitry 206 and the receive circuitry 208 can collectively function as the transceiver circuit 86A in FIG. 8, the transceiver circuit 86B in FIG. 10, or the transceiver circuit 86C in FIG. 11. The power amplifier circuit 10A of FIG. 1, the power amplifier circuit 10B of FIG. 4, the power amplifier circuit 10C of FIG. 6, the power amplifier circuit 126 in FIG. 10, or the power amplifier circuit 142 in FIG. 11 may be provided between the antenna switching circuitry 210 and the transmit circuitry 206 and/or the receive circuitry 208.

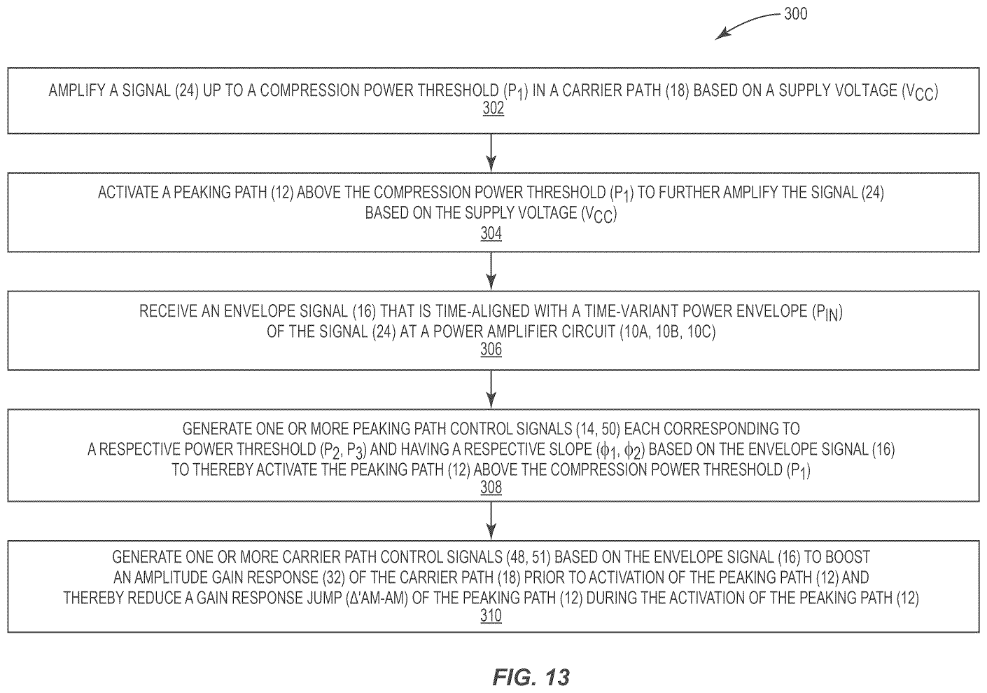

In an embodiment, it is possible to improve efficiency and linearity in the power amplifier circuit 10A of FIG. 2, the power amplifier circuit 10B of FIG. 4, and the power amplifier circuit 10C of FIG. 6 in accordance with a process. In this regard, FIG. 13 is a flowchart of an exemplary process 300 for improving efficiency and linearity in the power amplifier circuit 10A of FIG. 2, the power amplifier circuit 10B of FIG. 4, and the power amplifier circuit 10C of FIG. 6.

Herein, the process 300 includes amplifying the signal 24 up to the compression power threshold P₁ in the carrier path 18 based on the supply voltage V_{CC} (step 302). The process 300 also includes activating the peaking path 12 above the compression power threshold P₁ to further amplify the signal 24 based on the supply voltage V_{CC} (step 304). The process 300 also includes receiving the envelope signal 16 that is time-aligned with the time-variant power envelope P_{IN} of the signal 24 at the power amplifier circuit 10A, 10B, 10C (step 306). The process 300 also includes generating the peaking path control signals 14, 50 each corresponding to the respective power threshold P₂, P₃ and having the respective slope φ₁, φ₂ based on the envelope signal 16 to thereby activate the peaking path 12 above the compression power threshold P₁ (step 308). The process 300 also includes generating the carrier path control signals 48, 51 based on the envelope signal 16 to boost the amplitude gain response 32 of the carrier path 18 prior to activation of the peaking path 12 and thereby reduce the gain response jump Δ′AM-AM of the peaking path 12 during the activation of the peaking path 12 (step 310).

Those skilled in the art will recognize improvements and modifications to the preferred embodiments of the present disclosure. All such improvements and modifications are considered within the scope of the concepts disclosed herein and the claims that follow.

What is claimed is:

1. A power amplifier circuit comprising:
a carrier path configured to amplify a signal up to a compression power threshold based on a supply voltage;
a peaking path activated above the compression power threshold to further amplify the signal based on the supply voltage; and
a power amplifier control circuit configured to:
receive an envelope signal that is time-aligned with a time-variant power envelope of the signal at the power amplifier circuit;
generate one or more peaking path control signals each corresponding to a respective power threshold and having a respective slope based on the envelope signal to thereby activate the peaking path above the compression power threshold; and
generate one or more carrier path control signals based on the envelope signal to boost an amplitude gain response of the carrier path prior to activation of the peaking path and thereby reduce a gain response jump of the peaking path during the activation of the peaking path.

2. The power amplifier circuit of claim 1, wherein:
the carrier path comprises a carrier driver amplifier and a carrier output amplifier coupled in series;
the peaking path comprises a peaking driver amplifier and a peaking output amplifier coupled in series; and
the power amplifier control circuit comprises:
an analog processing circuit configured to pre-distort the envelope signal to thereby generate the one or more peaking path control signals and the one or more carrier path control signals;
a peaking path control circuit configured to provide each of the one or more peaking path control signals to a respective one of the peaking driver amplifier and the peaking output amplifier to thereby activate the peaking path; and
a carrier path control circuit configured to provide each of the one or more carrier path control signals to the carrier driver amplifier and the carrier output amplifier to thereby control the carrier path and boost the amplitude gain response of the carrier path prior to activation of the peaking path.

3. The power amplifier circuit of claim 2, wherein the peaking path control circuit is further configured to activate both the peaking driver amplifier and the peaking output amplifier concurrently based on an identical peaking activation threshold.

4. The power amplifier circuit of claim 2, wherein the peaking path control circuit is further configured to activate the peaking driver amplifier and the peaking output amplifier sequentially based on different peaking activation thresholds.

5. The power amplifier circuit of claim 1, wherein the power amplifier control circuit is further configured to pre-distort the envelope signal based on one or more local environmental variations in the power amplifier circuit, wherein the one or more local environmental variations comprises one or more of a variation in the supply voltage, a temperature variation, a load voltage standing wave ratio (VSWR) variation, a semiconductor process variation, and a part-to-part variation.

6. The power amplifier circuit of claim 1, wherein the power amplifier control circuit is further configured to perform amplitude-amplitude (AM-AM) linearization and amplitude-phase (AM-PM) linearization in one or more of the peaking path and the carrier path based on one or more local environmental variations detected in the power amplifier circuit.

7. The power amplifier circuit of claim 1, wherein the power amplifier control circuit is further configured to perform each of an amplitude-amplitude (AM-AM) linearization and an amplitude-phase (AM-PM) linearization in the peaking path based on a respective set of local environmental variations detected in the power amplifier circuit.

8. A method for improving power amplifier efficiency and linearity in a power amplifier circuit comprising:
amplifying a signal up to a compression power threshold in a carrier path based on a supply voltage;
activating a peaking path above the compression power threshold to further amplify the signal based on the supply voltage;
receiving an envelope signal that is time-aligned with a time-variant power envelope of the signal at the power amplifier circuit;
generating one or more peaking path control signals each corresponding to a respective power threshold and having a respective slope based on the envelope signal to thereby activate the peaking path above the compression power threshold; and
generating one or more carrier path control signals based on the envelope signal to boost an amplitude gain response of the carrier path prior to activation of the peaking path and thereby reduce a gain response jump of the peaking path during the activation of the peaking path.

9. A wireless transmission circuit comprising:
a transceiver circuit comprising:
a baseband circuit configured to generate a digital signal; and
a signal processing circuit configured to convert the digital signal into a signal having a time-variant power envelope;
a power management integrated circuit (PMIC) configured to generate a supply voltage based on a configuration signal received from the transceiver circuit; and
a power amplifier circuit comprising:
a carrier path configured to amplify the signal up to a compression power threshold based on the supply voltage; and
a peaking path activated above the compression power threshold to further amplify the signal based on the supply voltage; and
a power amplifier control circuit configured to:
receive an envelope signal that is time-aligned with the time-variant power envelope of the signal at the power amplifier circuit;
generate one or more peaking path control signals each corresponding to a respective power threshold and having a respective slope based on the envelope signal to thereby activate the peaking path above the compression power threshold; and
generate one or more carrier path control signals based on the envelope signal to boost an amplitude gain response of the carrier path prior to activation of the peaking path and thereby reduce a gain response jump of the peaking path during the activation of the peaking path.

10. The wireless transmission circuit of claim 9, further comprising:
an envelope tracking integrated circuit (ETIC) configured to generate an envelope tracking (ET) voltage based on the envelope signal; and
an ET power amplifier circuit configured to amplify a second signal based on the ET voltage.

11. The wireless transmission circuit of claim 9, wherein the transceiver circuit further comprises:
a time alignment circuit configured to time-align a time-variant amplitude of the digital signal with the time-variant power envelope of the signal at the power amplifier circuit; and
a driver circuit configured to generate the envelope signal based on the time-variant amplitude of the digital signal and provide the envelope signal to the power amplifier circuit.

12. The wireless transmission circuit of claim 9, wherein the power amplifier control circuit is further configured to pre-distort the envelope signal based on one or more local environmental variations in the power amplifier circuit, wherein the one or more local environmental variations comprise one or more of: a variation in the supply voltage, a temperature variation, a load voltage standing wave ratio (VSWR) variation, a semiconductor process variation, and a part-to-part variation.

13. The wireless transmission circuit of claim 9, wherein the transceiver circuit further comprises:
a time alignment circuit configured to time-align a time-variant amplitude of the digital signal with the time-variant power envelope of the signal at the power amplifier circuit;
an envelope digital pre-distortion (DPD) circuit configured to pre-distort the time-aligned digital signal to thereby generate a pre-distorted digital envelope signal; and
a driver circuit configured to generate the envelope signal from the pre-distorted digital envelope signal and provide the envelope signal to the power amplifier circuit.

14. The wireless transmission circuit of claim 13, wherein the power amplifier control circuit is further configured to:
receive the envelope signal from the transceiver circuit;
pre-distort the envelope signal based on one or more local environmental variations to generate the one or more peaking path control signals each corresponding to a respective power threshold and having a respective slope to thereby activate the peaking path; and
pre-distort the envelope signal based on the one or more local environmental variations to generate a carrier path control signal to thereby boost the amplitude gain response of the carrier path prior to activation of the peaking path.

15. The wireless transmission circuit of claim 14, wherein the one or more local environmental variations comprise one or more of: a variation in the supply voltage, a temperature variation, a load voltage standing wave ratio (VSWR) variation, a semiconductor process variation, and a part-to-part variation.

16. The wireless transmission circuit of claim 9, wherein the transceiver circuit further comprises:
a time alignment circuit configured to digitally process the digital signal to thereby time-align a time-variant amplitude of the digital signal with the time-variant power envelope of the signal at the power amplifier circuit;
a pre-distortion circuit configured to pre-distort the time-aligned digital signal based on one or more local environmental variations obtained from the power amplifier circuit to thereby generate a pre-distorted digital envelope signal; and
a driver circuit configured to generate the envelope signal from the pre-distorted digital envelope signal to thereby activate the peaking path and linearize the carrier path in the power amplifier circuit.

17. The wireless transmission circuit of claim 16, wherein the one or more local environmental variations obtained from the power amplifier circuit comprise one or more of: a variation in the supply voltage, a temperature variation, a load voltage standing wave ratio (VSWR) variation, a semiconductor process variation, and a part-to-part variation.

18. The wireless transmission circuit of claim 9, wherein the power amplifier circuit further comprises an envelope processing circuit configured to generate the envelope signal based on the time-variant power envelope of the signal and time-align the envelope signal with the time-variant power envelope of the signal;
wherein the power amplifier control circuit is further configured to:
pre-distort the envelope signal to generate the one or more peaking path control signals each corresponding to a respective power threshold and having a respective slope to thereby activate the peaking path; and
pre-distort the envelope signal to generate a carrier path control signal to thereby boost the amplitude gain response of the carrier path prior to activation of the peaking path.
